(19) United States
(12) Patent Application Publication
(10) Pub. No.: US 2011/0265719 A1
(43) Pub. Date: Nov. 3, 2011

(54) REACTION CHAMBER

(75) Inventors: Janne Peltoniemi, Otalampi (FI); Pekka Soininen, Helsinki (FI)

(73) Assignee: BENEQ OY, Vantaa (FI)

(21) Appl. No.: 13/143,314

(22) PCT Filed: Feb. 8, 2010
(86) PCT No.: PCT/FI10/50077

§ 371 Date: Jul. 5, 2011

(30) Foreign Application Priority Data
Feb. 9, 2009 (FI) 20095124

(51) Int. Cl. C23C 16/00

(52) U.S. Cl. 118/715

(57) ABSTRACT

A reaction chamber for an atomic layer deposition reactor is provided. The reaction chamber includes outer walls for providing a reaction space inside the reaction chamber. At least one of the outer walls of the reaction chamber is made from a flexible thinsheet.

### BACKGROUND OF THE INVENTION

The invention relates to a reaction chamber according to the preamble of claim 1, and particularly to a reaction chamber for an atomic layer deposition reactor, the reaction chamber comprising outer walls for providing a reaction space inside the reaction chamber.

Conventionally, a reaction chamber for an ALD reactor, a reactor used in an atomic layer deposition process, is formed from several thick massive plates wherein the necessary flow channels are provided e.g. by milling or drilling. In order to achieve a three-dimensional channel system, a plurality of such plates are placed on top of one another. Alternatively, a massive, thick and rigid flange is provided to which other necessary parts are further welded or screwed. Yet another prior art solution is to use a tubular reaction chamber into which substrates are inserted.

A problem with the above-described arrangements is that although the temperature balance of the prior art reaction chambers is good and well-controllable and they are self-supporting structures, they are expensive to manufacture because during manufacture, a vast majority of the material of their parts is machined off, which means that the material costs also become high. The machining is also slow and cumbersome in order to achieve a desired accuracy. Further, when the size of the reaction chamber increases, the durability and form-retaining capacity of these massive structures present another problem owing to the stress caused by their weight. The relative movements of the massive rigid parts of the reaction chamber have to be matched extremely accurately in order to prevent the parts of the reaction chamber from being damaged. This makes the structure of the reaction chamber complex. A tubular reaction chamber, in turn, is cumbersome to implement for large substrates and, in addition, in a tubular reaction chamber, good gas flow control and material efficiency are difficult to achieve.

### BRIEF DESCRIPTION OF THE INVENTION

An object of the invention is thus to provide a reaction chamber for an ALD reactor so as to enable the aforementioned problems to be solved. The object of the invention is achieved by a reaction chamber according to the characterizing part of claim 1, which is characterized in that at least one of the outer walls of the reaction chamber is made from a flexible thinsheet.

Preferred embodiments of the invention are disclosed in the independent claims.

In the present invention, outer walls of a reaction chamber of an atomic layer deposition (ALD) reactor are made at least partly from a thinsheet, which may be e.g. a steel thinsheet or a corresponding other thinsheet made from metal. The reaction chamber may be assembled from two or more thinsheets that are placed on top of one another and/or inside one another. Preferably, the thinsheet parts are shaped and placed such that they enable a reaction space of the reaction chamber and/or gas flow channels in the reaction chamber to be provided. In such a case, the reaction chamber may consist e.g. of a front plate through which gas fittings are brought to the reaction chamber, a back plate, and an intermediate sheet placed therebetween. These three thinsheet parts enable the reaction space of the reaction chamber and the gas flow channels in the reaction chamber to be provided. Alternatively, only one or more of the outer walls is/are made from a thinsheet while some of the outer walls, in turn, may be made from rigid or massive pieces.

In this context, a thinsheet refers to thin sheets that may be worked by cutting, forming, and bending. A thinsheet is made from metal, such as steel, aluminium or copper and, when necessary, it may also be coated. Generally, a thinsheet refers to a sheet whose thickness is 6 mm or less.

An advantage of the present invention is that it enables a reaction chamber to be manufactured in an inexpensive manner for large-area substrates. In addition, a thinsheet structure enables a reaction chamber structure which may be opened in a simple manner to be achieved. Further, a reaction chamber made from thinsheets is light-weight, so it may be disassembled even by one worker only. Furthermore, since the thinsheet is easy to fashion into various shapes and forms, the thinsheets, and thus the reaction chamber, may easily be provided with desired forms and shapes. The flexibility of the thinsheet makes it possible to achieve tightness of the reaction chamber easily since the thinsheet enables the reaction chamber to be provided with an at least partly flexible and adaptive structure. The flexible structure of the reaction chamber, in turn, lowers the manufacture tolerance requirements and the relative movement accuracy requirements set for the parts of the reaction chamber.

### BRIEF DESCRIPTION OF THE FIGURES

The invention is now described in closer detail in connection with the preferred embodiments and with reference to the accompanying drawings, in which:

FIG. 1 is a schematic side sectional view showing an embodiment of a reaction chamber according to the present invention;

FIG. 2 schematically shows the reaction chamber of FIG. 1 as seen from above; and

FIG. 3 is a schematic side sectional view showing a second embodiment of an outer wall structure of a reaction chamber according to the present invention.

### DETAILED DESCRIPTION OF THE INVENTION

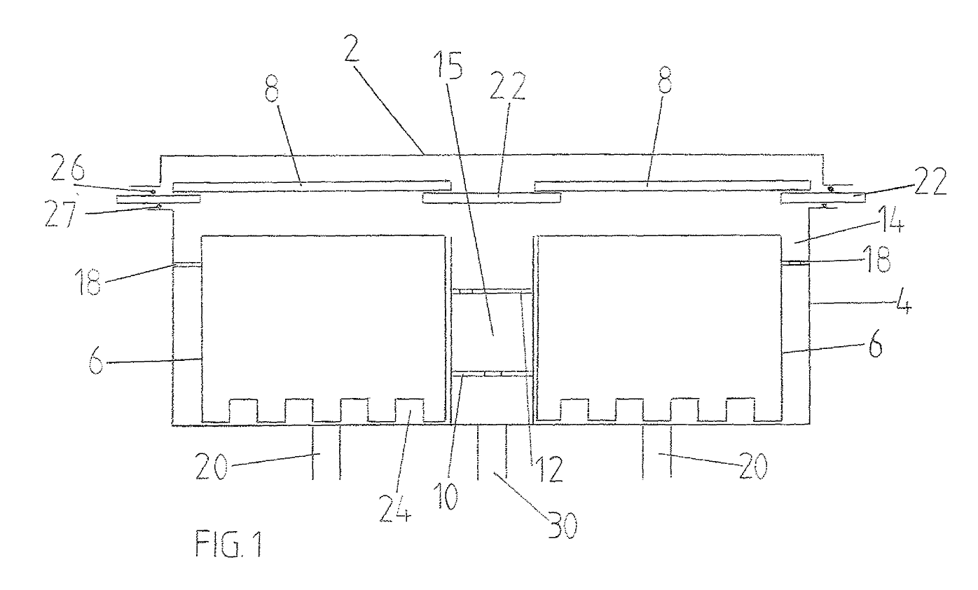

FIG. 1 shows an embodiment of a reaction chamber for an ALD reactor according to the present invention. Preferably, the reaction chamber according to the invention is arranged to be placed inside a vacuum chamber of the ALD reactor, but the reaction chamber as such may also provide a vacuum chamber and a reaction chamber, in which case it is no longer necessary to place the reaction chamber inside a separate vacuum chamber. The reaction chamber shown in FIG. 1 comprises a first sheet 2 and a second sheet 4 which are made from a thinsheet, preferably a flexible thinsheet, and which provide a reaction space therewithin. In this solution, the upper first sheet 2 serves as a back plate of the reaction chamber while the lower second sheet 4 serves as a front plate of the reaction chamber, through which front plate gases are fed to and discharged from the reaction chamber. The first sheet 2 and the second sheet 4 are arranged to be placed against one another in order to tighten the reaction space. The structure of the reaction chamber according to the invention may further be stiffened by means of an edge flange. According to FIG. 1, the first and the second sheet 2, 4 constitute the outer walls of the reaction chamber. The first sheet 2 constitutes a cover plate of the reaction chamber while the second sheet 4 constitutes a bottom plate and side walls of the reaction chamber, as shown in FIG. 1. The first sheet 2 and the second sheet 4, and thus, correspondingly, the cover plate, the bottom plate as well as the side walls of the reaction chamber, are made from a flexible thinsheet, which makes the structure of the reaction chamber flexible. In a preferred case, the first sheet 2 and the second sheet of the reaction chamber are made from a monolayer, substantially at least somewhat flexible thinsheet. When the first sheet 2 and the second sheet 4 are placed against one another, the flexible thinsheet enables the structure of the reaction chamber to yield and adapt to the shape and position of the first and the second sheet 2, 4, whereby the reaction chamber closes up tightly. Herein, a cover plate refers to an openable wall or plate of the reaction chamber and to its wall or a plate fixedly connected to the side walls by a bottom plate. However, it is to be noted that the cover plate and/or the bottom plate may be made movable in order to open or close the reaction chamber.

According to FIG. 1, the second sheet 4 is made trough-like or box-like such that it is open at the top. A substrate 8 is arranged to be fed to between the first and the second sheet 2, 4 to be processed by an ALD process. In FIG. 1, the reaction chamber is provided such that two parallel reaction spaces are formed therein, each enabling the substrate to be processed therein simultaneously. The space formed by the first and the second sheet 2, 4 therewithin is divided into two parts by a gas feed channel 15 which preferably extends across the reaction chamber and extends from the bottom of the second sheet 4 upwards, according to FIG. 1. Gas is led to the gas feed channel 15 through a gas feed pipe 30 connected to the bottom of the second sheet 4. Thus, gas flows in the gas channel 15 upwards, towards the first sheet 2. The gas feed channel 15 is provided with gas distribution means 10, 12 which serve to distribute the gas as evenly as possible over the entire width and length of the gas feed channel 15, and to bring its flow to a desired speed and level. One or more gas distribution means 10, 12 may be provided successively in the gas flow direction. The gas distribution means 10, 12 may be implemented e.g. as impact plates or as aperture plates 10, 12 provided with apertures of predetermined size and shape in a predetermined pattern or order. The gas feed channel 15 and/or the gas distribution means 10, 12 may also be made from a thinsheet. A gap 14, in turn, is preferably provided on all sides between the intermediate sheet 6 and the second sheet 4, in other words on all sides of the intermediate sheet 6 except on a side of the intermediate sheet 6 opposite to the gas feed channel 15. According to FIG. 1, the gap 14 is provided with one or more gas guiding means 18 arranged successively in the gas flow direction to control and guide the gas flow into the gap 14 and away from the space between the first sheet 2 and the intermediate sheet 6. The gas guiding means 18 may be implemented e.g. as an aperture plate 18 according to FIG. 1, which is provided with apertures of predetermined size and shape in a predetermined pattern or order. The apertures in the aperture plate 18 may also differ in size at different points of the aperture plate 18.

Intermediate sheets 6 are installed on both sides of the gas feed channel 15, inside the second sheet 4. The intermediate sheets 6 may also be installed inside the second sheet 4 such that they provide a gas feed channel 15 therebetween. In this embodiment, the intermediate sheets 6 are fashioned in a trough-like or box-like manner, and they have an open bottom or lower part. In other words, this trough-like intermediate sheet 6 has no bottom. In addition, the intermediate sheets 6 are shaped such that a gap 14 is provided between their vertical sides and the side edges of the second sheet 4. Further, the lower edges of the vertical sides of the intermediate sheets 6 are provided with cuts or holes 24. In FIG. 1, these holes 24 are implemented as a tooth system to form holes when the lower edges of the vertical sides of the intermediate sheet are against the bottom of the second sheet 4. Moreover, the bottom of the second sheet 4 is provided with gas discharge fittings 20 through which gas flows or is sucked out of the reaction chamber. These gas discharge fittings 20 are herein placed at the bottom of the second sheet 4 at an area covered by both intermediate sheets 6 and, in FIG. 1, at the centre of this area. In such a case, according to FIG. 1, gas from the gas feed channel 15 flows to the top of and over both intermediate sheets 6 from between the intermediate sheet 6 and the first sheet 2. Owing to the pressure and flow rate of the gas fed from the gas feed channel 15 and/or the suction or vacuum supplied from the gas discharge fitting 20, from the space between the intermediate sheet 6 and the first sheet 2 the gas flows into the gap 14 between the second sheet 4 and the intermediate sheet. After the gas has flowed down-wards along the gap 14, through the aperture plate 18 and all the way to the bottom of the second sheet 4, the gas is allowed to flow through the holes or cuts 24 provided at the lower edge of the vertical sides of the intermediate sheet 6 into the trough-like shape of the intermediate sheet 6, i.e. into the space between the bottom of the second sheet 4 and the intermediate sheet 6. From this space between the second sheet 4 and the intermediate sheet 6, the gas flows or becomes sucked further along the gas discharge fitting 20 out of the reaction chamber. The space between the bottom of the second sheet 4 and the intermediate sheet 6 thus serves as a so-called suction chamber which balances the suction of gas out of the reaction chamber, stores any excess of fed gas, and also serves as a pre-filter when gases that have not reacted in the reaction space are allowed to flow into this suction chamber.

In the embodiment according to FIG. 1, the substrates 8 are placed on a substrate support or supports 22. When the substrates 8 are loaded into the reaction chamber, the first sheet 2 and the second sheet 4, or the edges or edge sections thereof, settle against the substrate support 22, thus closing and tightening the reaction chamber. Alternatively, the first sheet 2 and the second sheet 4 may settle directly against the substrate 8, closing up the reaction chamber. The first and the second sheet 2, 4 may be provided with seals 26, 27, respectively, which settle against the substrate support 22 or the substrate 8 on the opposite sides thereof when the reaction chamber is closed. The seals 26, 27 may be e.g. elastomer seals or the like. In the embodiment of FIG. 1, the seals 26, 27 are installed at the edges of the first and the second sheet 2, 4 or in the vicinity thereof.

In the solution according to FIG. 1, the substrate 8 is placed in the reaction chamber such that its lower surface is in contact with the gases. Thus, it can be seen in FIG. 1 that the reaction chamber is formed such that its reaction space is provided substantially between the substrate 8 and the intermediate sheet 6. In such a case, the substrate 8 as well as its supports 22 form part of the reaction space and/or define the reaction space. Such a solution enables the flow dynamics of the reaction chamber to be optimized. In order to keep the substrate 8 tightly in place such that no disadvantageous leakage points are generated in the reaction chamber, the first sheet 2 may be provided with prestressing means (not shown) for pressing the substrate 8 against the substrate support 22 and/or against the second sheet 4 in order to ensure the tightness of the reaction chamber. In an alternative solution, the prestressing means provided in the first sheet 2 may press the substrate support against the second sheet 4. In still another solution, the prestressing means may be provided in the second sheet 4 such that they press the substrate 8 and/or the substrate support 22 against the first sheet. The prestressing means may be produced e.g. by a plurality of springs arranged side by side. Alternatively, the prestressing means may be made from another flexible material or structure, such as an elastomer seal, for instance.

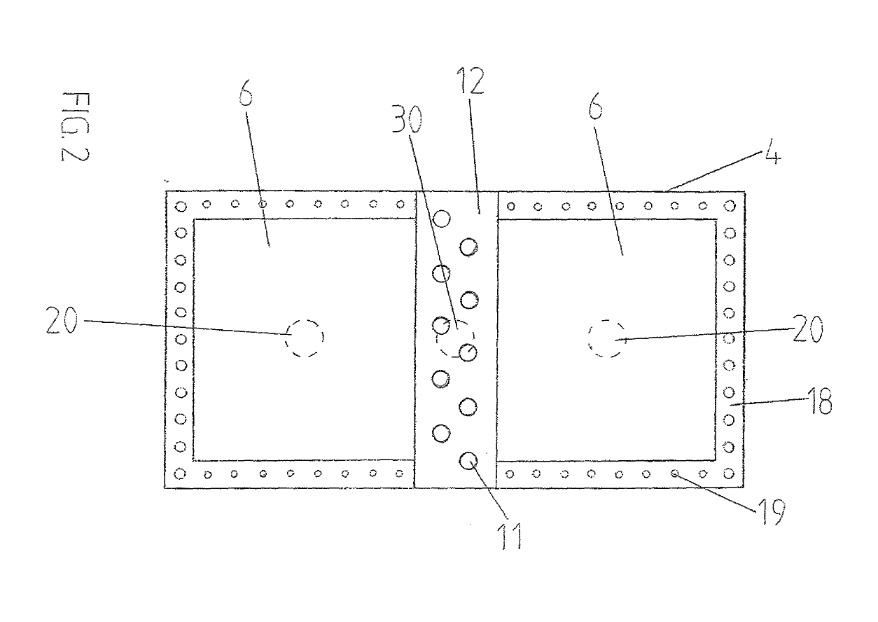

FIG. 2 is a top view showing the reaction chamber of FIG. 1 when the first sheet 2 as well as the substrates 8 and the substrate supports 4 have been removed. In other words, FIG. 2 shows the second sheet 4 and the intermediate sheet 6 and the gas flow channels. It can be seen in FIG. 2 how gas is fed from the gas flow channel through apertures 11 of the aperture plate 12 over the entire length of one side of the intermediate sheet 6 into the reaction space defined, according to FIG. 1, between the intermediate sheet 6 and the substrate 8. From the reaction space, in turn, gas is sucked out over the three other sides of the intermediate sheet 6 through apertures 19 of the aperture plate 18. Thus, a circumference formed by the side walls of the reaction space of the reaction chamber is made active over its entire length such that the entire length of the circumference is utilized in reaction space gas exchange in order to feed and discharge gas. In an alternative manner, this may be implemented such that the gas feed fittings of the reaction chamber are provided such that gas may be fed to the reaction space over the length of one or more side walls thereof, and that the gas discharge fittings of the reaction chamber are provided such that gas may be discharged from the reaction space over the length of one or more side walls thereof. In such a case, the circumference formed by the side walls of the reaction space of the reaction chamber is divided into a gas feed zone and a gas discharge zone. In the reaction chamber of FIG. 2, comprising a rectangular reaction space, the gas feed fittings are provided such that gas may be fed to the reaction space over the length of one side wall thereof, while the gas discharge fittings are provided such that gas may be discharged from the reaction space over the length of three side walls thereof. Of course, the same may also be applied to the reaction space of a circular or oval or similarly shaped reaction chamber, wherein the circumference formed by the side walls of the reaction space consists of one curved side wall. In such a case, this one side wall is divided into a gas feed zone and a gas discharge zone, as described above.

The present invention is not restricted to the embodiment described above in connection with FIGS. 1 and 2, but the structure of the reaction chamber may vary quite extensively without deviating from the present invention. The essential point in the reaction chamber of the present invention is that it is made from two or more thinsheets that are placed on top of and/or inside one another and shaped and dimensioned in order to provide a reaction chamber. Preferably, the flow channels 15, 14, 24 and/or the reaction space of the reaction chamber are provided by means of the shapes of the thinsheets such that the formation of flow channels and/or reaction space inside the reaction chamber necessitates no separate parts. The shape or form of the reaction chamber according to FIG. 1 may be fashioned e.g. such that the intermediate sheet 6 is provided as a straight plate extending between the gas feed channel 15 and the second sheet 4. In such a case, the edges of the intermediate sheet, or the vicinity thereof, the edges abutting on the vertical side walls of the second sheet 4, are provided with holes corresponding with the apertures 19 of the aperture plate 18 in order to discharge gas from the reaction space. Such an intermediate sheet also forms a suction chamber in a space between the intermediate sheet 6 and the second sheet 4. In addition, it is further to be noted that the reaction chamber may be provided such that it comprises only one reaction chamber space rather than two adjacent reaction chamber spaces, as the embodiment according to FIGS. 1 and 2. However, it is also possible to utilize machined parts in the structure to make it stiffer, whereby unbent sheets may be used which, in turn, may be tightened against these auxiliary pieces. Such a part may be used e.g. for replacing the edges of the sheet 4 and the bent forms provided therein. In an alternative embodiment, the gas feed fittings are provided such that gas is divided in two or more directions, preferably in the middle of the reaction chamber. In such a case, the reaction chamber has no outer walls, but the suction is located at the outer circumference at the perimeter. In other words, the gas feed fittings are provided such that gas may be fed in two or more directions towards the side walls of the reaction chamber in order to discharge gas over the length of the side walls.

Preferably, the reaction chamber according to the invention is made to be opened such that the first and the second sheet 2, 4 are arranged to be moved in a vertical direction with respect to one another in order to open and close the reaction chamber such that the substrate 8 is loadable in a horizontal direction to between the first and the second sheet 2, 4 and/or removable from therebetween when the reaction chamber is in an open state, wherein the first and the second sheet 2, 4 reside separately at a distance from one another, and such that the substrate 8 is processable by the ALD process in a closed state of the reaction chamber. In such a case, e.g. the second sheet 4, and thus also the intermediate sheet 6, may be moved in the vertical direction in order to open and close the reaction chamber. In the open state, the first sheet 2 and the second sheet 4 are separate from one another, and the substrate is feedable and removable from therebetween from the reaction chamber. In the closed state, the first sheet and the second sheet 2, 4 reside against one another, and the substrate is processable by an ALD process in the reaction chamber.

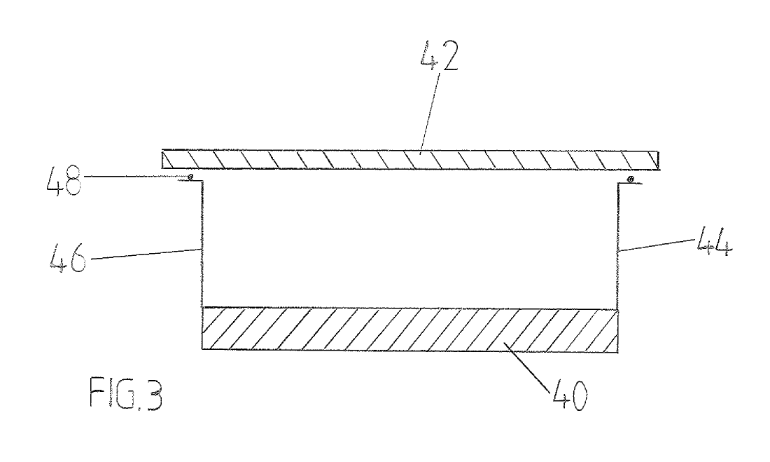

In an alternative solution, only some of the outer walls of the reaction chamber may be made from a flexible thinsheet. FIG. 3 shows an outer wall structure of a reaction chamber, which comprises a massive rigid bottom plate 40 and a massive rigid cover plate 42. The reaction chamber further comprises side walls 44, 46 made from a flexible thinsheet. According to FIG. 3, the side walls 44 and 46 are provided fixedly, e.g. by fastening, to the bottom plate 40. The cover plate 42 and the bottom plate 40 are made movable with respect to one another in order to open and close the reaction chamber for loading a substrate to the reaction chamber and for removing it therefrom. The side walls 44, 46 move along with the bottom plate 40 if it is moved. Upon closing the reaction chamber, the side walls 44, 46 and the cover plate 42 are placed against one another in to a position shown in FIG. 3, wherein seals 48 seal the cover plate 42 and the side walls 44, 46 against one another. The side walls 44, 46 made from a flexible thinsheet provide the reaction chamber with an at least partly flexible and non-rigid structure. The reaction chamber of FIG. 3 may comprise all the same details and features, such as flow channels, as the reaction chamber of FIGS. 1 and 2, but the first sheet 2 of FIGS. 1 and 2 made from a thinsheet has been replaced by the rigid cover plate 42 and the second sheet by the rigid bottom plate 4 as well as by the flexible side walls 44, 46. A side wall may also be provided as a cylindrical sheath. Thus, in the embodiment according to FIG. 3, the side walls 44, 46 are made to extend between the first and the second sheet 42, 40.

According to the present invention, at least one of the outer walls of the reaction chamber is made from a flexible thinsheet in order to provide the reaction chamber with a non-rigid and adaptive structure. In other words, in the reaction chamber according to FIG. 3, only one of the side walls 44, 46 may be made from a thinsheet while the rest of the side walls may be rigid. Correspondingly, the cover plate 42 and/or the bottom plate 40 may be made from a thinsheet while the side walls 44, 46 are rigid structures. The cover plate 42 and the bottom plate 40 may both be sheet-like parts or, alternatively, other parts forming a wall of the reaction chamber.

It is apparent to a person skilled in the art that as technology advances, the basic idea of the invention may be implemented in many different ways. The invention and its embodiments are thus not restricted to the above-described examples but may vary within the scope of the claims.

1. A reaction chamber for an atomic layer deposition reactor, the reaction chamber comprising outer walls for providing a reaction space inside the reaction chamber, wherein at least one of the outer walls of the reaction chamber is made from a flexible thinsheet.

2. A reaction chamber as claimed in claim 1 wherein the outer walls of the reaction chamber are formed from a first sheet and a second sheet made from a flexible thinsheet, which provide a reaction space therebetween in order to receive and process a substrate by an ALD process.

3. A reaction chamber as claimed in claim 2, wherein the reaction chamber further comprises an intermediate sheet which is placed between the first and the second sheet and which, together with the first sheet sheet, forms a reaction space.

4. A reaction chamber as claimed in claim 3, wherein the intermediate sheet is made from a thinsheet.

5. A reaction chamber as claimed in claim 2, wherein the structure of the reaction chamber is stiffened by means of edge flanges provided in the first sheet or in the second sheet or both.

6. A reaction chamber as claimed in claim 2, wherein the first sheet is a back plate of the reaction chamber while the second sheet is a front plate of the reaction chamber, through which front plate gas feed and discharge fittings are brought into the reaction chamber.

7. A reaction chamber as claimed in claim 1 wherein the outer walls of the reaction chamber are formed by means of the first sheet, the second sheet and one or more side sheets ex-tending between the first and the second sheet, at least one of the first sheet second sheet and the side sheets being made from a flexible thinsheet.

8. A reaction chamber as claimed in claim 2, wherein at least one of the side walls is made from a flexible thinsheet.

9. A reaction chamber as claimed in claim 1, wherein flow channels and/or the reaction space of the reaction chamber are provided by means of thinsheets.

10. A reaction chamber as claimed in claim 1, wherein a circumference formed by the side walls of the reaction space of the reaction chamber is made active over its entire length such that the entire length of the circumference is utilized in reaction space gas exchange in order to feed and discharge gas.

11. A reaction chamber as claimed in claim 10, wherein the gas feed fittings of the reaction chamber are provided such that gas is feedable into the reaction space at the circumference formed by the side walls over the length of one or more side walls, and that the gas discharge fittings of the reaction chamber are provided such that gas is dischargeable from the reaction space at the circumference formed by the side walls over the length of one or more side walls.

12. A reaction chamber as claimed in claim 1, wherein in a reaction chamber comprising a rectangular reaction space, the gas feed fittings are provided such that gas is feedable into the reaction space at the circumference formed by the side walls over the length of one side wall, and the gas discharge fittings are provided such that gas is dischargeable from the reaction space at the circumference formed by the side walls over the length of three side walls.

13. A reaction chamber as claimed in claim 1, wherein the gas feed fittings of the reaction chamber comprise, arranged successively in a gas flow direction, one or more gas distribution means for distributing a gas flow evenly at the circumference formed by the side walls over the entire length of the side wall, wherefrom gas is fed to the reaction space.

14. A reaction chamber as claimed in claim 10, wherein the gas feed fittings are provided such that gas is feedable in two or more directions towards the side walls of the reaction chamber in order to discharge gas at the circumference formed by the side walls over the length of the side walls.

15. A reaction chamber as claimed in claim 3, wherein the intermediate sheet is placed between the first and the second sheet such that a gap through which gas is discharged from the reaction space is formed between the intermediate sheet and the second sheet.

16. A reaction chamber as claimed in claim 15, wherein the second sheet is made trough-like such that together with the intermediate sheet, it forms a suction chamber whereto gas to be discharged from the reaction space is led through the gap.

17. A reaction chamber as claimed in claim 16, wherein the suction chamber is equipped with a suction channel provided in the second sheet in order to discharge gas from the suction chamber.

18. A reaction chamber as claimed in claim 16, wherein the gap is provided with one or more gas guiding means for guiding a flow of the gas to be discharged from the reaction space.

19. A reaction chamber as claimed in claim 13, wherein the gas distribution means and/or the gas guiding means are provided as an aperture plate.

20. A reaction chamber as claimed in claim 19, wherein the first and the second sheet are arranged to be placed against one another in order to close the reaction chamber.

21. A reaction chamber as claimed in claim 2, wherein the first and the second sheet are arranged to be placed against the substrate or a substrate support such that the substrate and/or the substrate support form(s) part of the reaction chamber.

22. A reaction chamber as claimed in claim 2, wherein the first sheet or, correspondingly, the second sheet is provided with prestressing means for pressing the substrate against the substrate support and/or against the second sheet or, correspondingly, the first sheet.

23. A reaction chamber as claimed in claim 2, wherein the first and the second sheet are arranged to be moved in a vertical direction with respect to one another in order to open and close the reaction chamber such that the substrate is loadable in a horizontal direction to between the first and the second sheet and/or removable from therebetween when the reaction chamber is in an open state, wherein the first and the second sheet reside separately at a distance from one another and such that the substrate is processable by an atomic layer deposition process in a closed state of the reaction chamber.
